(19) United States
(12) Patent Application Publication
(10) Pub. No.: US 2023/0363293 A1
(43) Pub. Date: Nov. 9, 2023

(54) SUPERCONDUCTING QUANTUM CIRCUIT APPARATUS

(71) Applicant: NEC Corporation, Tokyo (JP)

(72) Inventors: Akira Miyata, Tokyo (JP); Tsuyoshi Yamamoto, Tokyo (JP)

(73) Assignee: NEC Corporation, Tokyo (JP)

(21) Appl. No.: 18/101,700

(22) Filed: Jan. 26, 2023

(30) Foreign Application Priority Data
Mar. 31, 2022 (JP) 2022-060282

(51) Int. Cl. H10N 60/80; H10N 60/12; G06N 10/40

(52) U.S. Cl. CPC H10N 60/12; G06N 10/40; H10N 60/805

(57) ABSTRACT

A superconducting quantum circuit apparatus includes a resonator including a SQUID including at least two Josephson junctions in a loop, a magnetic field application part that includes a conductor portion, a current passing therethrough generating a magnetic flux penetrating through the SQUID, the current supplied from a current control part, and a parallel LC circuit including an inductor and a capacitor each made of a superconducting material, the inductor and the capacitor having respective one ends connected in common to the magnetic field application part and respective other ends connected in common to a current path from the current control part.

### FIELD

### CROSS REFERENCE TO RELATED APPLICATIONS

This application is based upon and claims the benefit of the priority of Japanese patent application No. 2022-060282, filed on Mar. 31, 2022, the disclosure of which is incorporated herein in its entirety by reference thereto.

The present invention relates to a superconducting quantum circuit apparatus.

### BACKGROUND

Regarding a related technology of a superconducting quantum circuit apparatus, there is known a quantum circuit (qubit circuit) using a Josephson parametric oscillator, as disclosed in Patent Literature (PTL) 1. FIG. 1A schematically illustrates a configuration of the Josephson parametric oscillator of the related technology. FIG. 1A is based on FIG. 1 of PTL 1. In the present description, for convenience of explanation, an oscillator (Josephson parametric oscillator) 10 is assumed to include an input/output capacitor 107 (C₁) and a magnetic field application part 11 (termed as an electromagnetic wave application part in PTL 1) in addition to a resonator 12.

The resonator 12 may include a superconducting nonlinear resonator that includes a Josephson junction (JJ) acting as a nonlinear inductance. The resonator 12 may include a SQUID (superconducting quantum interference device) 108 that includes a superconducting part 103, a Josephson junction 101 (JJ1), a superconducting part 104, and a Josephson junction 102 (JJ2) connected in a ring shape. An electrode in a center of the resonator 12 is a conductor portion (waveguide) 105 made of a superconducting material. A capacitor (C0) 106 is connected between the conductor portion (waveguide) 105 and a ground. The superconducting part 104 has one end connected to the ground. In FIG. 1A, only for simplicity’s sake, a size of SQUID 108 (size of the superconducting part 103, etc.) is illustrated to be almost the same as that of the conductor portion (waveguide) 105. However, the superconducting part 103 constituting the SQUID 108 is structurally very small in size.

The conductor portion 105 in the resonator 12 is connected to a readout line (signal line) 16 via the input/output capacitor (C1) 107 and is connected to a readout part (readout circuit) 13 via a circulator 17 disposed on a readout line (signal line) 16. In FIG. 1A, the input/output capacitor (C1) 107 represents a capacitive coupling between an end of the conductor portion 105 (open end), which is formed on a wiring layer on a substrate (not shown), and an end of the readout line 16, which is spaced apart from the conductor portion 105 and faces it. The capacitor (C0) 106 represents a capacitance component such as a floating capacitance between the conductor portion (waveguide) 105 and ground. The input/output capacitor (C1) 107 and the capacitor (C0) 106 represents a capacitance component such as a floating capacitance instead of an actual capacitor.

A magnetic field application part 11 a conductor portion (waveguide) through which a current supplied by a current control part 14 flows. The current control part 14 supplies a microwave signal of a frequency (2f0) almost twice a resonance frequency (f0) of the resonator 12 to the magnetic field application part 11. The magnetic field application part 11 generates a magnetic flux penetrating through the SQUID 108 (SQUID loop) responsive to the microwave signal to cause the resonator 12 to oscillate at a frequency (f0).

A state of the resonator 12 is outputted via the input/output capacitor (C1) 107 to the readout part 13 through the readout line 16 and the circulator 17. A phase of an oscillation signal of a resonance frequency of the resonator 12 varies in accordance with a state of a qubit. Therefore, a state of the qubit can be determined from the phase of the oscillation signal of the resonator 12. A readout pulse output from a signal generator 18 to the readout line 16 via the circulator 17 is set to an extent of intensity so as not to excite a quantum system. Therefore, readout is performed by an amplifier (low noise amplifier), not shown, in the readout part 13, so that a state of the qubit is not destroyed (or changed) due to noise during measurement.

FIG. 1B is a diagram illustrating a configuration illustrated in FIG. 1A as a circuit diagram. The oscillator 10 includes the resonator 12, the magnetic field application part 11, and the input/output capacitor (C1) 107. The input/output capacitor (C1) 107 capacitively couples an end of the conductor portion (waveguide )105 and an end of the readout line 16. Inductors L3 and L4, with each one end thereof connected to ground via the superconducting part 104, are nonlinear inductors and correspond to the Josephson junctions 101 and 102(JJ1 and JJ2), respectively. An inductor L2, which is connected in common to other ends of Josephson junctions JJ1 and JJ2, respectively, corresponds to the superconducting part 103 in FIG. 1A. An inductor L1 corresponds to the conductor portion 105 in FIG. 1A. R1 represents a resistance component (insulation resistance), etc. between the conductor portion 105 and the superconducting part 103 in FIG. 1A and ground (The resistor R1 may be omitted in a circuit diagram such as a high-frequency equivalent circuit diagram).

A power loss of the oscillator 10 degrades an internal Q-value. As is well known, the power loss of the oscillator 10 is caused by heat dissipation, radiation, and leakage.

Part of an electric power of a resonance frequency in the oscillator 10 passes through a magnetic field coupling (inductive coupling) between the SQUID 108 and the magnetic field application part 11 to the current control part 14 and is consumed in the current control part 14. This is equivalent to leakage of an electric power from the oscillator 10, which degrades the internal Q-value of the oscillator 10.

PTL1: Japanese Unexamined Patent Application Publication No. 2018-11022

Non Patent Literature (NPL) 1: Chung Wai Sandbo Chang, “Parametric Microwave Amplification using a Tunable Superconducting Resonator,” A thesis presented to the University of Waterloo in fulfilment of the thesis requirement for the degree of Master of Applied Science in Electrical and Computer Engineering, 2015

### SUMMARY

As described with reference to FIG. 1A and FIG. 1B, a loss of the oscillator 10 degrade an internal Q-value. A loss of the oscillator 10 include heat, radiation, and leakage. For example, part of an electric power at a resonance frequency of the oscillator 10 passes through magnetic field coupling (inductive coupling) between the SQUID 108 and the magnetic field application part 11 to the current control part 14 and is consumed in the current control part 14. This degrades the internal Q-value of the oscillator 10.

Therefore, in order to suppress the degradation of the internal Q-value of the oscillator 10, it is necessary to suppress a pass (transmission) characteristic at the resonance frequency, between the oscillator 10 and the current control part 14.

In the case when the pass (transmission) characteristic at the resonance frequency is suppressed between the resonator 12 and the current control part 14, the part of the electric power at the resonance frequency can be suppressed to transmit to the current control part 14 to be consumed therein. In this case, the pass (transmission) characteristic of DC and a frequency twice the resonance frequency must be maintained between the current control part 14 and the oscillator 10.

It is an object of the present disclosure to provide a superconducting quantum circuit apparatus which is configured to suppress a passage of an electric power at a resonance frequency of a Josephson parametric oscillator to a current control part.

According to the present disclosure, there is provided a superconducting quantum circuit apparatus, including:
a resonator including a SQUID (superconducting quantum interference device) including at least two Josephson junctions in a loop;
a magnetic field application part that includes a conductor portion, a current passing therethrough generating a magnetic flux penetrating through the SQUID, the current supplied from a current control part; and
a parallel LC circuit including an inductor and a capacitor each made of a superconducting material, the inductor and the capacitor having respective one ends connected in common to the magnetic field application part and respective other ends connected in common to a current path from the current control part.

According to the present disclosure, it is possible to provide a superconducting quantum circuit apparatus which is configured to suppress a passage of an electric power at a resonance frequency of a Josephson parametric oscillator to a current control part to suppress a degradation of an internal Q-value of a resonator that configures an oscillator.

### BRIEF DESCRIPTION OF THE DRAWINGS

FIG. 1A is a diagram schematically illustrating a related technology.

FIG. 1B is a diagram illustrating a configuration of a circuit (equivalent circuit) of the related technology.

FIG. 2A is a diagram illustrating an example embodiment.

FIG. 2B is a diagram illustrating a configuration of a circuit (equivalent circuit) of the example embodiment.

FIG. 2C is a diagram illustrating an analysis result for the equivalent circuit of the example embodiment.

FIG. 3A is a cross sectional view schematically illustrating an example of a configuration of the example embodiment.

FIG. 3B is a cross sectional view schematically illustrating an example of a configuration of the example embodiment.

FIG. 4A is a perspective exploded view schematically illustrating an example of a structure of the example embodiment.

FIG. 4B is a plan view schematically illustrating an example of a planar configuration the example embodiment.

FIG. 5A is a diagram illustrating an electromagnetic field analysis result for the structure of the example embodiment.

FIG. 5B is a diagram schematically illustrating a circuit parameter obtained by the structure of the example embodiment.

FIG. 6 is a diagram schematically illustrating an internal Q-value of the example embodiment.

FIG. 7A is a diagram illustrating an electromagnetic field analysis result (a magnetic field distribution at an instant when a maximum value of a magnetic field intensity that penetrating through the SQUID is obtained) for a comparative example (a structure without a parallel LC circuit).

FIG. 7B is a diagram illustrating an electromagnetic field analysis result (a magnetic field distribution at an instant when a maximum value of a magnetic field intensity that penetrating through the SQUID is obtained) for the example embodiment (a structure with a parallel LC circuit).

FIG. 8A is a diagram illustrating an inductor in the parallel LC circuit of the example embodiment.

FIG. 8B is a diagram illustrating an inductor in the parallel LC circuit of the example embodiment.

FIG. 9 is a diagram illustrating a capacitor in the parallel LC circuit of the example embodiment.

FIG. 10 is a diagram illustrating an example of a structure of a bump.

FIG. 11A is a diagram schematically illustrating a coupling by leakage.

FIG. 11B is a diagram schematically illustrating a measure against the coupling by leakage.

### EXAMPLE EMBODIMENTS

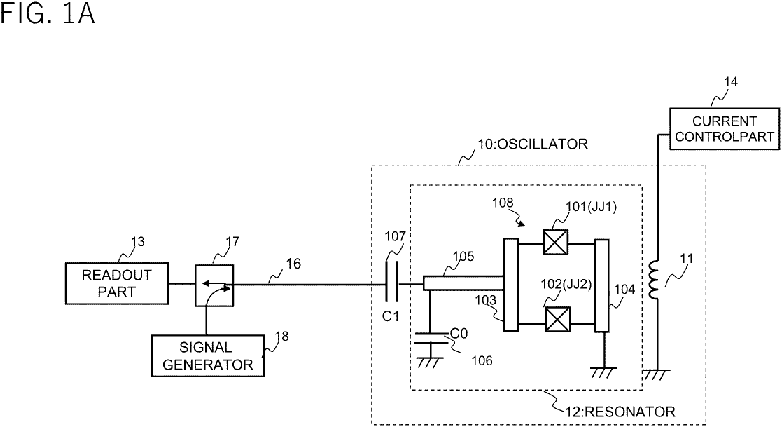

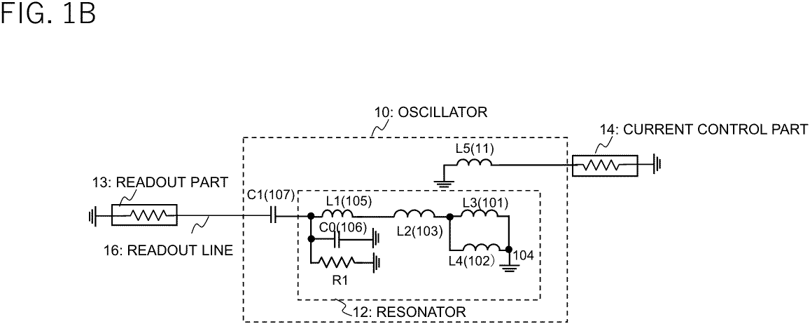

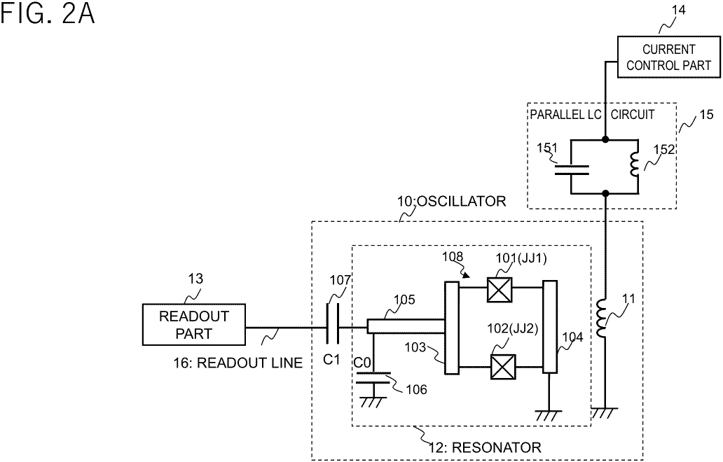

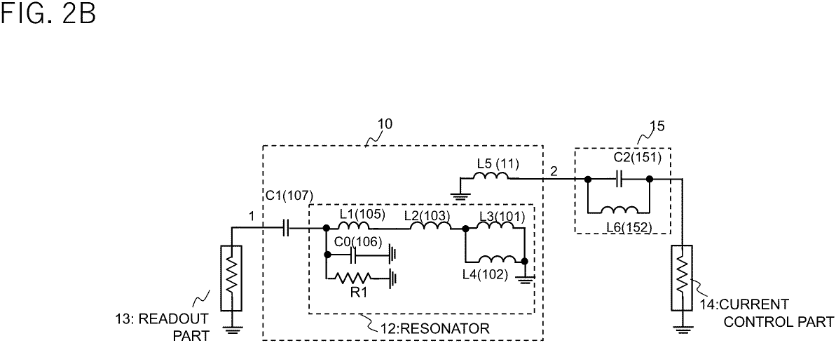

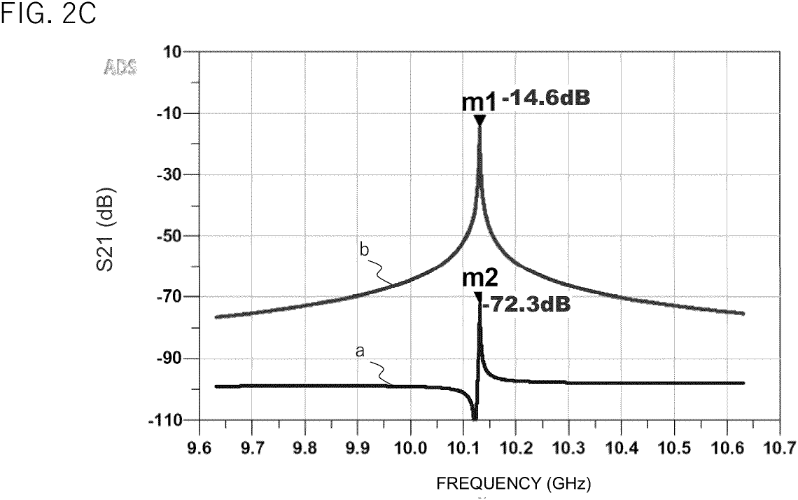

Several example embodiments of the present disclosure will be described. FIG. 2A is a diagram illustrating an example embodiment. In FIG. 2A, the same reference numerals (or symbols) are assigned to the same components illustrated in FIG. 1A. A resonator 12 includes a SQUID 108 including a superconducting part 103, a Josephson junction 101 (JJ1), a superconducting part 104, and a Josephson junction 102 (JJ2) connected in a ring shape. In FIG. 2A, an oscillator (Josephson parametric oscillator) 10 also includes an input/output capacitor 107 (C1) and a magnetic field application part 11 in addition to the resonator 12 as in FIG. 1A.

In the present example embodiment, in a current path from a current control part 14 to the magnetic field application part 11, there is inserted on a conductor portion (current path) made of a superconducting material, a parallel LC circuit 15 that includes an inductor 152 and a capacitor 151 each made of a superconducting material, connected in parallel. The parallel LC circuit 15 is also called a superconducting LC circuit because an electrode of the capacitor 151 and an inductor 152 are each made of a superconducting material. In FIG. 2A, the conductor portion 105 is of an elongated rectangular shape, only for the simplicity’s sake. The conductor portion 105 and superconducting part 103 may be of a shape as a cruciform of four arms including one arm has a portion connected to the SQUID 108 and another arm has a portion capacitively coupled with a readout line (signal line) 16.

FIG. 2B is a diagram illustrating a configuration of FIG. 2A as a circuit diagram (high frequency equivalent circuit diagram). In FIG. 2B. the oscillator 10 includes an input/output capacitor C1, for convenience of explanation. Inductors L3 and L4 (nonlinear inductors), which are connected to ground via a superconducting part 104, correspond to the Josephson junctions 101 and 102 (JJ1 and JJ2), respectively. An inductor L2, which is connected in common to the other ends of Josephson junctions JJ1 and JJ2, respectively, corresponds to the superconducting part 103. An inductor L1 corresponds to the conductor portion 105. C0 represents a capacitance value of a capacitor 106 between the conductor portion (waveguide) 105 and ground. R1 represents a resistance component (insulation resistance) between the conductor portion 105 and ground. L5 represents an inductance value of the magnetic field application part 11, C2 represents a capacitance value of the capacitor 151 in the parallel LC circuit 15, and L6 represents an inductance value of the inductor 152 in the parallel LC circuit 15.

An impedance ZLC of the parallel LC circuit 15 is given by

$$Z L C = \frac{1}{\frac{1}{i {L}_{6} ω} + i {C}_{2} ω}$$

where, a reactance of the inductor L6 and a reactance of the capacitor C2 are iL6ω, and 1/iC2ω (where, i²=-1), respectively. A combined impedance Z of the parallel LC circuit 15 and a current path (resistance R) connecting thereto is given by

$$Z = \frac{1}{1 / i {L}_{6} ω + i {C}_{2} ω} + R = \frac{R \left(1 - {L}_{6} {C}_{2} {ω}^{2}\right) + i {L}_{6} ω}{1 - {L}_{6} {C}_{2} {ω}^{2}} \qquad \text{(1)}$$

At an angular frequency

$${ω}_{0} = \sqrt{{L}_{6} {C}_{2}} \qquad \text{(2)}$$

the impedance Z′ reaches the maximum (infinity) and almost no current flows, wherein the parallel LC circuit 15 functions as a rejector circuit. That is, when a resonance frequency of the parallel LC circuit 15 is equal to a resonance frequency of the oscillator 10, the impedance Z of the parallel LC circuit 15 side seen from the oscillator 10 becomes maximum (infinite). An electromagnetic wave with a frequency equivalent to the resonance frequency of the oscillator 10 is prevented from propagating to the current control part 14.

According to the present example embodiment, since the parallel LC circuit 15 (reject circuit), which prevents passage of an electromagnetic wave with a frequency equivalent to the resonance frequency of the oscillator 10, is inserted between the current control part 14 and the magnetic field application part 11, a pass (transmission characteristic) at the resonance frequency can be significantly suppressed. Note that the insertion of the parallel LC circuit 15 has no effect on the pass (transmission) characteristic at a frequency twice the resonance frequency.

According to the present invention, coupling between the readout part (readout circuit)13 and the current control part 14 is suppressed, so that even when coupling between the resonator 12 and the magnetic field application part 11 is increased, degradation of an internal Q-value of the resonator 12 included in the oscillator 10 can be reduced. In addition, by increasing the coupling between the resonator 12 and the magnetic field application part 11, it is made possible to reduce a value of a microwave current (electric power) supplied from the current control part 14 to the magnetic field application part 11.

FIG. 2C shows a result of a high frequency circuit analysis for a circuit configuration illustrated in FIG. 2B. Transmission characteristics of a 2-port network (corresponding to transmission characteristics S_{2 1} and S_{1 2} of S parameter) (in dB), i.e., pass (transmission) characteristics (in dB) between the readout circuit 13 and the current control part 14 in FIG. 2B, are shown. A horizontal axis of FIG. 2C indicates a frequency (GHz (Giga Hertz)). In FIG. 2C, “a” indicates the transmission characteristic S_{2 1} when the parallel LC circuit 15 is connected, and “b” indicates the transmission characteristic S_{2 1} when the parallel LC circuit 15 is not connected.

The resonator 12 has a resonance frequency of about 10.1 GHz, and when the parallel LC circuit 15 is not connected, the transmission characteristic at) 10.1 GHz band signal (the transmission characteristic from the readout circuit 13 side to the current control part 14 side) is of about -14.6 dB (indicated as ml in FIG. 2C). When the parallel LC circuit 15 is connected, the transmission characteristic at 10.1 GHz band signals is of about -72.3 dB (indicated as m2 in FIG. 2C). This corresponds to a fact that transmission characteristic at 10.1 GHz-band electromagnetic wave, which is of about -14.6 dB, is further attenuated by about 60 dB using the parallel LC circuit 15.

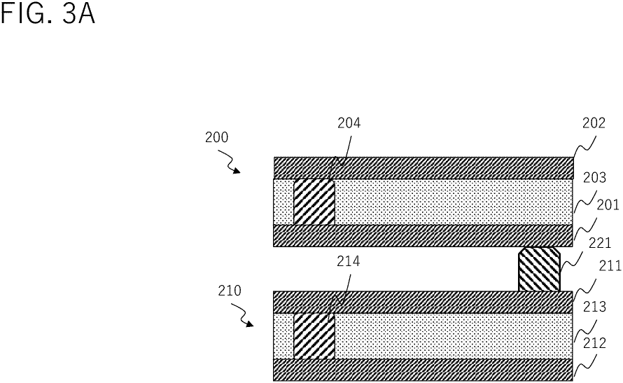

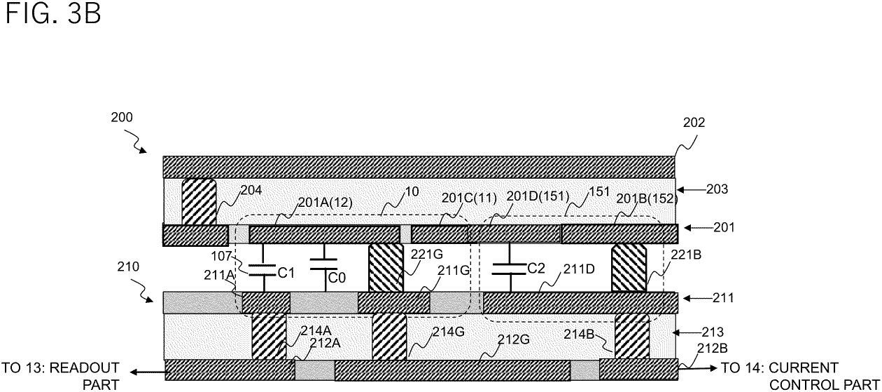

FIG. 3A illustrates a configuration of the present example embodiment. A superconducting quantum apparatus 1 according to the present example embodiment includes a first substrate (quantum chip) 200 and a second substrate (interposer substrate (or interposer)) 210. A quantum chip 200 includes, for example, a qubit. The qubit may be configured by the Josephson parametric oscillator, described above. The interposer substrate 210 is a wiring substrate which can conduct between a front circuit and a back circuit by a through via and is connected to the quantum chip 200 to realize a three-dimensional wiring structure.

As illustrated in FIG. 3A, the quantum chip 200 is face-down mounted on the interposer substrate 210 with a circuit face (a first wiring layer 201) thereof down. The quantum chip 200 includes the first wiring layer 201 and a second wiring layer 202 on a first face of a substrate 203 and a second face of a substrate 203 which is on a side opposite to the first substrate, respectively. The substrate 203 is composed by a silicon substrate. The first wiring layer 201 is formed by a wiring pattern formation process in a semiconductor fabrication process (superconducting thin film deposition, resist coating, exposure/developing, etching, etc.).

The interposer substrate 210 includes a third wiring layer 211 and a fourth wiring layer 212 on a first face and a second face of a substrate 213, respectively. The substrate 213 is composed by a silicon substrate, for example. The quantum chip 200 and the interposer substrate 210 are preferably made both from a material with the same thermal expansion coefficient. As a non-limiting example, in case where these substrates are made from silicon (Si), high-resistance silicon of 10 kΩcm (kiloohm centimeter) or higher is suitable, and a high resistance of 20 kΩcm or higher is more preferable. The interposer substrate 210 is disposed for conversion between a fine pitch of the quantum chip 200 and a pitch of an external circuit (such as a package substrate). The interposer substrate 210 may be configured such that the third wiring layer 211 corresponds to a pitch of the wiring pattern of the first wiring layer 201 of the quantum chip 200, and fourth wiring layer 212 corresponds to a pitch of the external circuit (package substrate, etc.). Alternatively, one or more interposer substrates 210 on each of which a quantum chip 200 is mounted may be mounted on yet another interposer substrate.

As a non-limiting example, in addition to silicon, other electronic materials such as sapphire and compound semiconductor materials (Group IV (GeSn, etc.), Group III-V (GaAs, GaN, GaP,11 GaSb, InAs, InP, InS, etc.), Group II-VI (ZnS, ZnSe)) may be used for the substrate 203 of the quantum chip 200 and the substrate 213 of the interposer substrate 210. Single crystal is preferable, but polycrystalline or amorphous is also acceptable.

As a non-limiting example, the first and third wiring layers 201 and 211 may each include a superconducting material, such as niobium (Nb), niobium nitride, aluminum (Al), indium (In), lead (Pb), tin (Sn), rhenium (Re), palladium (Pd), titanium (Ti), tantalum (Ta), tantalum nitrides, or a niobium (Nb) alloy including at least one of these. The superconducting material is not limited to niobium (Nb), but may include niobium nitride, aluminum (Al), indium (In), lead (Pb), tin (Sn), rhenium (Re), palladium (Pd), titanium (Ti), tantalum (Ta), tantalum nitrides, or an alloy including at least one of these. The second and fourth wiring layers 202 and 212, a through via(s) connecting the first wiring layer 201 and the second wiring layer 202, and a through via(s) connecting the third wiring layer 211 and the fourth wiring layer 212 can be made of the same superconducting material as the first and third wiring layers 201 and 211.

The first wiring layer 201 of the quantum chip 200 and the third wiring layer 211 of the interposer substrate 210 are connected by a bump(s) (metal protrusion electrode(s)) 221.

The inductor 152 is formed on, for example, the first wiring layer 201. Alternatively, it may be formed by the first wiring layer 201 and the third wiring layer 211. The capacitor 151 may be formed by the first wiring layer 201 and the third wiring layer 211.

A periphery of a conductor of the resonator 12 is surrounded by the through via(s) 204 of the substrate 203 of the quantum chip 200, and the bump(s) 221.

A gap between a conductor (201A (105 in FIG. 2A)) of the resonator 12 and the through via 204 of the first substrate 203 may preferably be one hundredth (1/100) wavelength or less of a free space wavelength. For example, at 10 GHz, the free space wavelength λ₀ is 3 × 10^8 (m)/10 × 10^9 =3 cm, and one hundredth of it is not more than 300 µm (micrometer).

A gap between a conductor (for example, 105 in FIGS. 2A or 201A in FIG. 3A) of the resonator 12 and the bump 221 may preferably be one hundredth (1/100) wavelength or less of a free space wavelength.

The through via 204 of the first substrate 203, through via 214 of the second substrate 213, and further the bump 221 are preferably arranged at an interval of one hundredth (1/100) wavelength or less of a free space wavelength, respectively.

As a non-limiting example, as illustrated in drawings, the bump 221 is a protrusion suitable for controlling a height of a spacing between substrates to be joined, and can be selected from any ones such as a columnar (cylindrical, polygonal, etc.), conical (can include conical, pyramidal, as well as truncated cone, truncated pyramid, etc.), spherical, or rectangular shape. The top of the bump 221 may be formed to have a partially flat shape. The bump 221 is made of a normal conducting material such as copper or silicon dioxide (SiO₂), and may have a surface covered with a film of a superconducting material. In this case, a superconducting wiring in the first wiring layer 201 of the quantum chip 200 is connected to a superconducting wiring in the third wiring layer 211 of the interposer substrate 210 via the superconducting bump 221. Alternatively, the bump 221 may be formed by laminated superconducting materials. The bump 221 is provided on the third wiring layer 211 side of the interposer substrate 210.

As a non-limiting example, the bump 221 has a diameter of an order of 2 µm or larger, and considering connection reliability, 10 µm or larger is desirable, and 100 µm or larger is more suitable. Height of the bump 221 is of an order of 1 µm or larger. If there is a thermal expansion difference between the substrates to be bonded via the bump 221, the connection reliability can be improved by increasing the height of the bump. If a structure that transmits a signal by coupling through a void between substrates bonded by the bump 221 is included, in a range of 2 to 10 µm is suitable for the height of the bump. The bump 221 may be formed on the third wiring layer 211 during a fabrication process of the interposer substrate 210. Bonding of the quantum chip 200 and the bump 221 may be done by solid phase bonding, for example. Inside of a refrigerator is evacuated and a gap between the first wiring layer 201 and the third wiring layer 211 is in a vacuum state. Among solid-phase bonding methods, surface activation bonding and ultrasonic bonding may be used. In addition, melt joining may be used if high temperature can be applied during bonding, and pressure welding may be used if resin can be used.

FIG. 3B schematically illustrates an arrangement of each element illustrated in FIG. 2A in a three-dimensional wiring as illustrated in FIG. 3A. In FIG. 3B, 201A (12) on the first wiring layer 201 of the quantum chip 200 represents the resonator 12 (such as a conductor portion 105). A wave guide (end portion of 105 in FIG. 2A) of a wiring 201A (12) on the first wiring layer 201 is capacitively coupled via a gap (vacuum state) with a coupling portion (wiring (electrode) 211A on the third wiring layer 211) that couples with a readout part 13.

In FIG. 3B, the wiring 211A on the third wiring layer 211 of the interposer substrate 210 is connected to the wiring 212A on the fourth wiring layer 212 via a through via 214A, and via the wiring 212A on the fourth wiring layer 212, connected to the readout part 13 outside of the refrigerator.

In the first wiring layer 201 of the quantum chip 200, 201C (11) represents the magnetic field application part 11 made of a superconducting material, through which a current from the current control part 14 flows to generate a magnetic field (flux) penetrating through the SQUID 108 of the resonator 12. In FIG. 3B, the magnetic field application part 11 is provided on the first wiring layer 201 of the quantum chip 200, but the magnetic field application part 11 may be provided on an area on the third wiring layer 211 facing the SQUID loop of the resonator 12 on the first wiring layer 201.

A wiring 201D (151) on the first wiring layer 201 represents a first electrode (upper electrode) of the capacitor 151 in the parallel LC circuit 15, and a wiring 211D on the third wiring layer 211 of the interposer substrate 210, opposing to the wiring 201D (151) on the first wiring layer 201, represents a second electrode (lower electrode) of the capacitor 151.

A wiring 201B (151) on the first wiring layer 201 of the quantum chip 200 represents the inductor 152 connected in parallel to the capacitor 151 in the parallel LC circuit 15. One end of the inductor 152, which is indicated 201B (152) on the first wiring layer 201, is connected to 201 D (151), which is the first electrode of the capacitor 151, and the other end thereof is connected to the wiring 211D (the second electrode of the capacitor 151) on the third wiring layer 211 of the interposer substrate 210 via a bump 221B. The wiring 211D on the third wiring layer 211 is connected to a wiring 212B on the fourth wiring layer 212 to be connected to the current control part 14 outside thereof via a through via 214B. A ground pattern (planer ground pattern, also called ground plane) on the first wiring layer 201 of the quantum chip 200 is connected to a ground pattern (ground plane) 212G on the fourth wiring layer 212 via a bump 221G, a pad (wiring) 211G on the third wiring layer 211 of the interposer substrate 210 and a through via 214G.

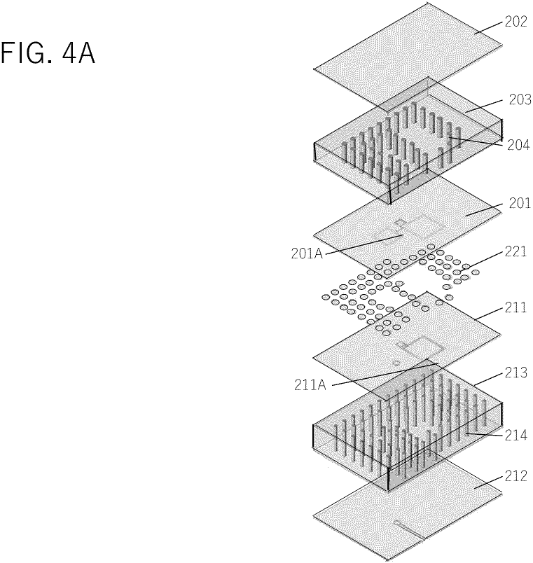

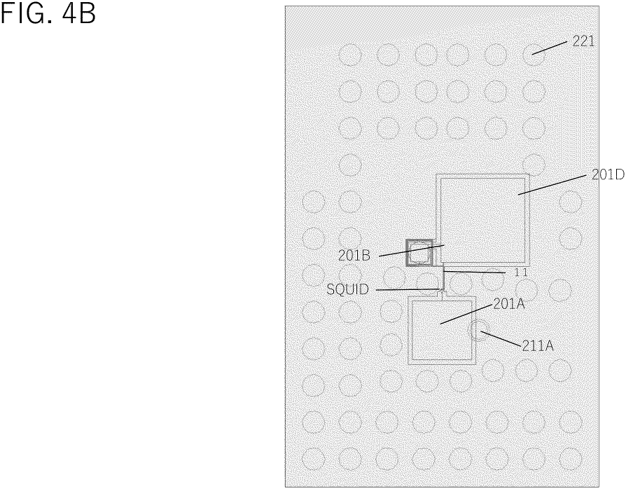

FIG. 4A is an exploded perspective view which schematically illustrates a three-dimensional structure illustrated in FIG. 3B. In FIG. 4A, through vias 204, illustrated as a circular cylinder, correspond to the through via 204 in FIG. 3, and represent a through via (ground via) connecting the ground pattern (ground plane) on the first wiring layer 201 and the ground pattern (ground plane) on the second wiring layer 202.

FIG. 4B schematically illustrates an example of wiring patterns of the first wiring layer 201 of the quantum chip 200, the third wiring layer 211 of the interposer substrate 210, and the bump 221. A double circle intersecting the conductor portion 105 (201A in FIG. 4A) represents a pad 211A on the third wiring layer 211. A circle arranged throughout the pattern represent the bump 221. A reference numeral 11 represents a magnetic field application part which is configured by a coplanar waveguide and is connected to one end of the inductor 152 (wiring 201 B (152) in FIG. 3B) and the first electrode (201D (151) on the first wiring layer in FIG. 3B). The other end of the inductor 152 (wiring 201D (152) in FIG. 3B) and the second electrode of the capacitor 151 are connected to a wiring (wiring 211D in FIG. 3B) on the third wiring layer 211, via the bump 221B (FIG. 3B). Note that the inductor 152 is configured with a quadrilateral spiral-shaped inductor, but it is, of course, not limited to such a shape.

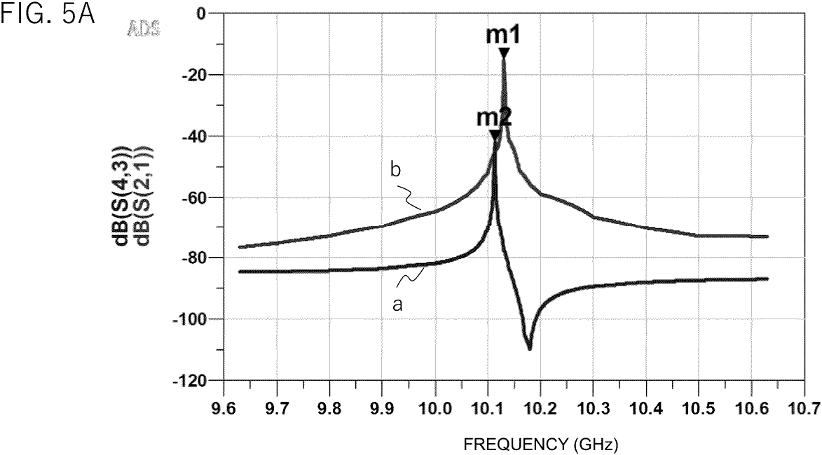

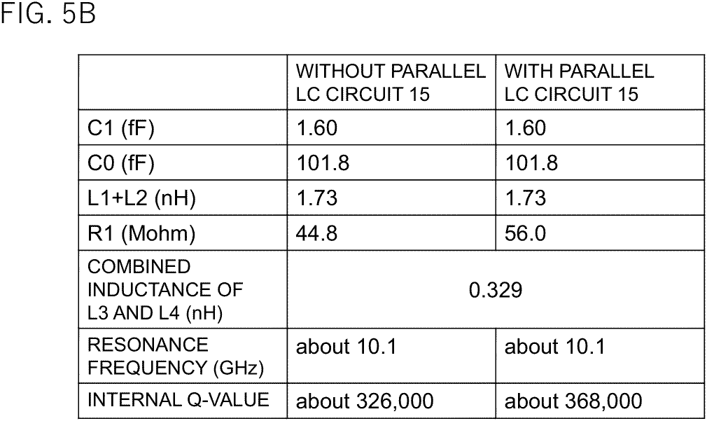

FIG. 5A shows a result of high-frequency electromagnetic field analysis to the three-dimensional structure described in FIG. 3A, FIG. 3B, FIG. 4A and FIG. 4B. The results illustrated therein indicates transmission characteristics of a 2-port network (corresponds to S21 of S parameter). The transmission characteristic (in decibel) between the readout circuit 13 and the current control part 14 in FIG. 2B is illustrated as compared to that of without the parallel LC circuit 15 (graph “b” in FIG. 5A). In the case when the parallel LC circuit 15 (graph “a” in FIG. 5A) is added, the maximum pass (transmission) characteristic to the current control part 14 through the magnetic field coupling (inductive coupling) between the SQUID 108 and the magnetic field application part 11 of the resonator 12 is -42.0 dB (m2 in FIG. 5A). Whereas without the parallel LC circuit 15, it is -15.1 dB (ml in FIG. 5A). Thus, by adding the parallel LC circuit 15, an electric power passing through to the current control part 14 can be reduced by about 27 dB.

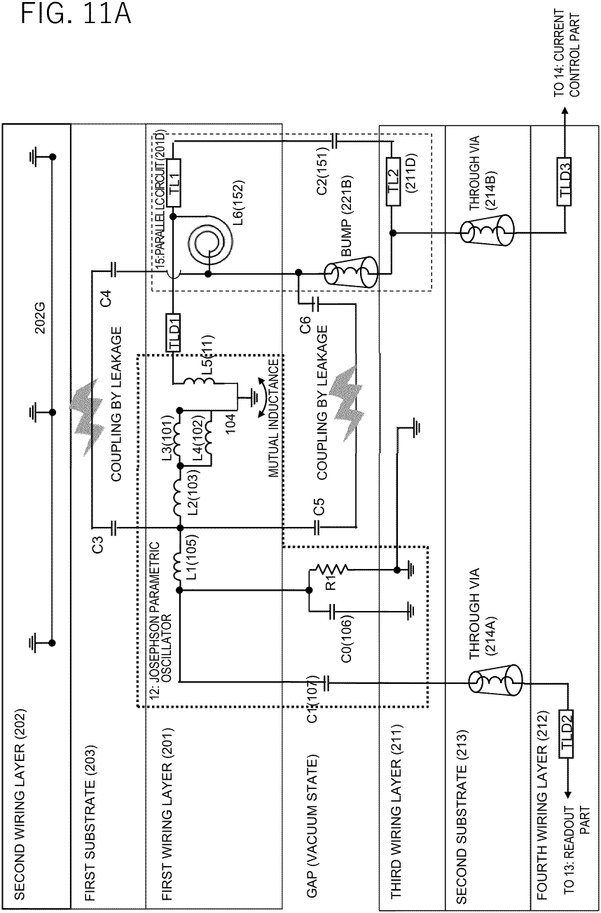

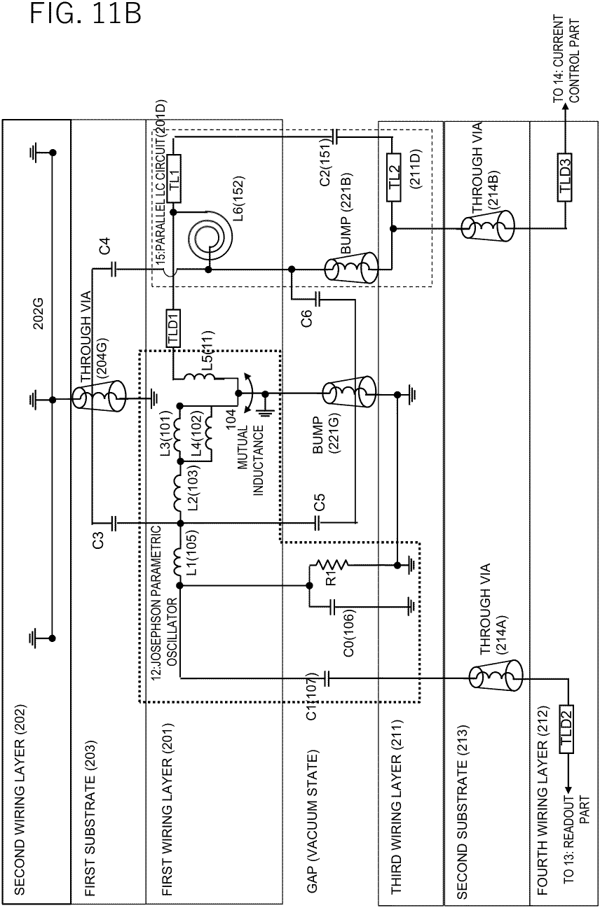

Note that this performance is obtained under a presumption that the first wiring layer 201 of the quantum chip 200 has a configuration in which it is interposed between the ground surface on the second wiring layer 202 opposing to the first wiring layer 201 and the ground pattern (ground plane) on the third wiring layer 211 using the bump 221 and the through via 204 which will be described with reference to FIG. 11B. The bump 221 and the through via 204 prevent spread of a leakage electromagnetic field whose intensity decreases exponentially with distance.

As for the parallel LC circuit 15, a degree of integration is not increased when a distance from the resonator 12 is increased. As illustrated in FIG. 3A and FIG. 3B, in the present example embodiment, a multi-layered structure (three-dimensional structure) with the bump 221 and the through vias 204 and 214 makes it possible to reduce a magnetic field coupling, which enables the parallel LC circuit 15 to be arranged close to the resonator 12.

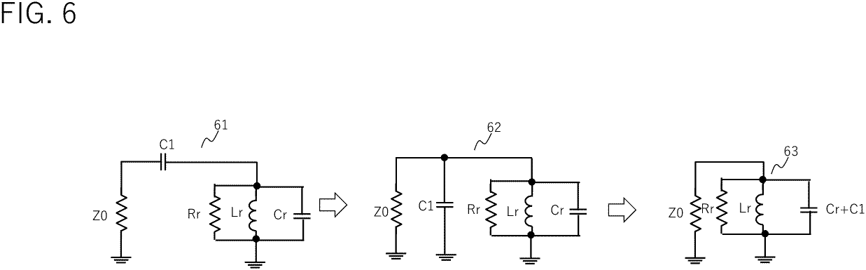

FIG. 6 is a diagram illustrating an internal Q-value, based on the description in NPL 1 (FIG. 5 and FIG. 6). A circuit 61 (a circuit illustrated on the left side of FIG. 6), in which a capacitor C₁ and a parallel RLC circuit (a parallel circuit with a resistive component Rr, an inductor Lr, and a capacitor Cr) connected in series with a transmission line (characteristic impedance of the transmission line: Z₀) corresponds to an equivalent circuit of the oscillator 10. A circuit 62 (a circuit illustrated in the center of FIG. 6) is obtained by applying a Norton transformation to the circuit 61 under the condition on which the following relation (3) holds.

$$1 > > {ω}^{2} {Z}_{0} {}^{2} {C}_{1} {}^{2} \qquad \text{(3)}$$

In the circuit 62, the transmission line (characteristic impedance: Z₀ ) and the capacitor C₁ are connected in parallel. The resistive component (insulation resistance) Rr, the inductor Lr, and a combined capacitance of capacitors C₁ and Cr connected in parallel, form a circuit 63 (a circuit illustrated on the right side of FIG. 6) of parallel RLC circuit.

Letting a combined impedance of the parallel RLC circuit is Z, then:

$$\frac{1}{Z} = \frac{1}{R} + \frac{1}{\frac{1}{i C ω}} + \frac{1}{i L ω} = \frac{1}{R} + i \left(C ω - \frac{1}{L ω}\right) \qquad \text{(4)}$$

From the above equation (4), an absolute value of the combined impedance Z is given as follows:

$$\frac{1}{\left|Z\right|} = \sqrt{\frac{1}{{R}^{2}} + {\left(C ω - \frac{1}{L ω}\right)}^{2}} \qquad \text{(5)}$$

When an angular frequency ω is given as follows,

$$ω = C ω - \frac{1}{L ω} \qquad \text{(6)}$$

that is when

$${ω}_{0} = \frac{1}{\sqrt{L C}} \qquad \text{(7)}$$

holds, the absolute value of the combined impedance Z reaches its maximum (the maximum value = R). An angular frequency at which the absolute value of the combined impedance Z is 1/√2 of the maximum value thereof will be found as follows:

$$\frac{1}{\sqrt{\frac{1}{{R}^{2}} + {\left(C ω - \frac{1}{L ω}\right)}^{2}}} = \frac{R}{\sqrt{2}} \qquad \text{(8)}$$

From the above equation (8),

$${\left(C ω - \frac{1}{L ω}\right)}^{2} = \frac{1}{{R}^{2}} \qquad \text{(9)}$$

Then,

$$C ω - \frac{1}{L ω} = \pm \frac{1}{R} \qquad \text{(10)}$$

The angular frequency ω (>0) is given by

$$ω = \frac{\pm \frac{1}{R C} + \sqrt{{\left(\frac{1}{R C}\right)}^{2} + \frac{4}{L C}}}{2} \qquad \text{(11)}$$

Letting two ωs denoted by ω₁ and ω₂ (ω₂ > ω₁ ), then

$${ω}_{2} - {ω}_{1} = \frac{1}{R C} \qquad \text{(12)}$$

Then, the internal Q-value of the parallel RLC circuit is given by the following equation (13).

$$Q = \frac{{ω}_{0}}{{ω}_{2} - {ω}_{1}} = R C {ω}_{0} = \frac{R}{L {ω}_{0}} \qquad \text{(13)}$$

Accordingly, the internal Q-value of the circuit 64 illustrated in FIG. 6 is given by the following equation (14).

$$Q = {R}_{r} \left(C r + C 1\right) {ω}_{0} \qquad \text{(14)}$$

In FIG. 5B, there are listed circuit parameters of the Josephson parametric oscillator 10 illustrated in FIG. 2B, which are obtained based on the result of the high frequency electromagnetic field analysis described in FIG. 5A. The capacitor C₁ (107) and the capacitor C0 (106) are in femtofarad (fF), an inductor L1+L2 is in nanohenry (nH), and a resistance R1 is in megaohm (Mohm). From these circuit parameters and the equation (13), it is found that the internal Q value of the Josephson parametric oscillator 10 with the parallel LC circuit 15 added is about 368000, while 326000 without the parallel LC circuit 15.

The increase in internal Q value in the case when the parallel LC circuit 15 is added is to an extent of 13%.

If a magnetic field coupling (also called inductive coupling) between the Josephson parametric oscillator 10 and the magnetic field application part 11 is reduced, it becomes necessary to increase a current supplied from the current control part 14 to the magnetic field application part 11, in order to generate a magnetic flux and/or a magnetic field penetrating through the SQUID 108 of the Josephson parametric oscillator 10, with the intensity same as that before the a magnetic field coupling is reduced. In accordance with the example embodiment, by adding the parallel LC circuit 15 to the Josephson parametric oscillator 10, it is possible to suppress an oscillation output leakage from the Josephson parametric oscillator 10 to the current control part 14 side (magnetic field application part 11 side), without extreme reduction of a magnetic field coupling between the Josephson parametric oscillator 10 and the magnetic field application part 11. It is possible to reduce the current supplied from the current control part 14 to the magnetic field application part 11 to generate the magnetic flux and/or the magnetic field penetrating through the SQUID 108.

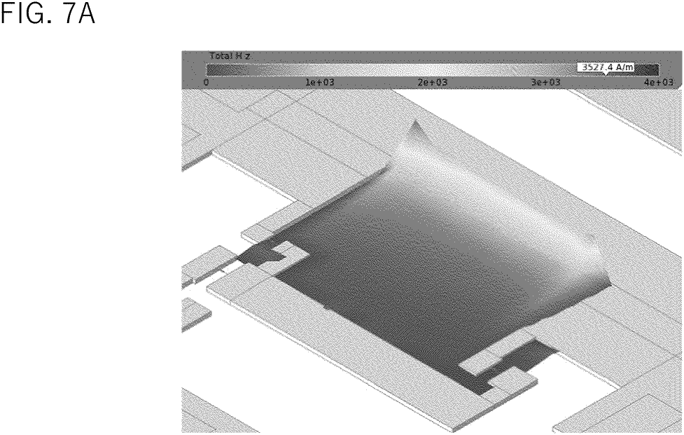

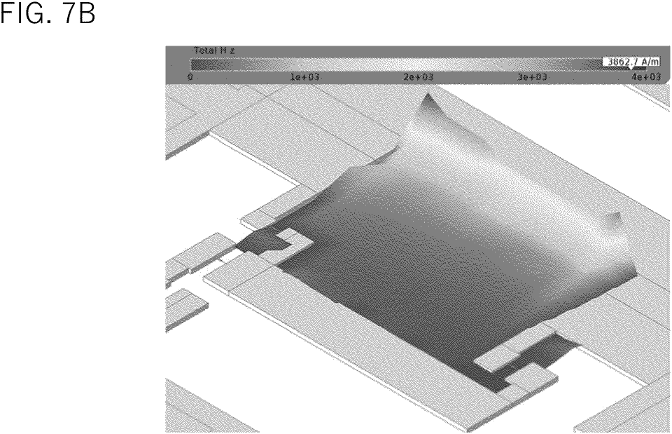

FIG. 7A and FIG. 7B illustrate a magnetic field distribution of an instantaneous value at which the maximum value of the magnetic field intensity penetrating through the SQUID 108 is obtained, when a signal of twice the frequency of the 10.1 GHz band, which is a resonance frequency of the Josephson parametric oscillator 10, is supplied from the current control part 14 to cause the Josephson parametric oscillator 10 to resonate. FIG. 7A illustrates a magnetic field distribution without the parallel LC circuit 15, in which the maximum magnetic field intensity is 3527.4 A/m. FIG. 7B illustrates a magnetic field distribution with the parallel LC circuit 15, in which the maximum magnetic field intensity is 3862.7 A/m. It is found that in the configuration where the parallel LC circuit 15 with the resonance frequency equal or nearly equal to that of the Josephson parametric oscillator 10, a magnetic field equivalent to that of the Josephson parametric oscillator 10 without the parallel LC circuit 15 can be applied to the SQUID 108. From this analysis result, it can be seen that an intensity of the signal applied by the current control part 14 to cause the Josephson parametric oscillator 10 to resonate is the same as that without the parallel LC circuit 15, wherein the signal applied is of twice the frequency of the 10.1 GHz, which is a resonance frequency of the Josephson parametric oscillator 10.

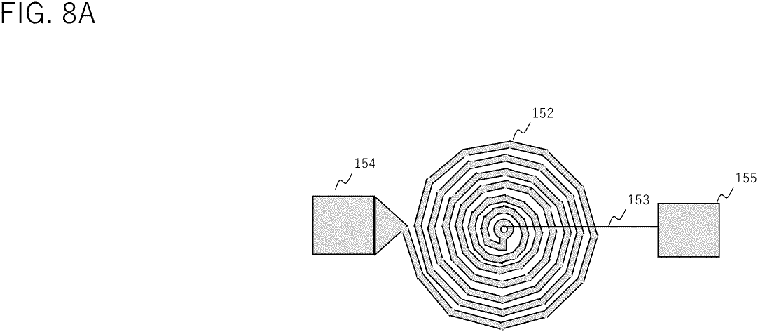

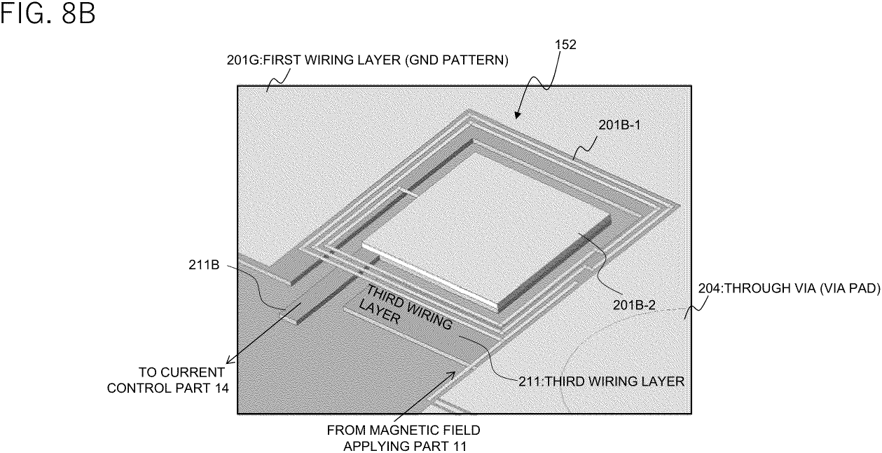

FIG. 8A schematically illustrates an example in which an inductor 152 in the parallel LC circuit 15 of the example embodiment is configured using a spiral inductor. Here, the inductor 152 is also denoted as the inductor 152 of a spiral type. An airbridge 153 is used for a part of a wiring of the inductor 152 of a spiral type. One end (center portion) of the inductor 152 of a spiral type is connected to a wiring pad 155 (wiring 201B (152) in FIG. 3B) by the airbridge 153. A wiring pad 154, which is the other end of the inductor 152 of a spiral type, is connected to the magnetic field application part 11 (FIG. 2A). The one end (center portion) of this inductor 152 may be connected to the wiring pad 155 formed by the electrode (FIG. 3B 211D) on the third wiring layer 211 of the capacitor 151 with a bump instead of airbridge 153.

The inductor 152 of the parallel LC circuit 15 may be constituted by a bump 221. Alternatively, the inductor 152 may be constituted by a through via 204. which passes through the substrate 203 of the quantum chip 200.

FIG. 8B illustrates another configuration example of the inductor 152 of the parallel LC circuit 15. The inductor 152 has a configuration of the first wiring layer 201 – a bump – the third wiring layer 211. Reference numeral 201G designates a planar ground pattern (GND pattern) of the first wiring layer 201. The inductor 152 includes a square-shaped spiral portion 201B-1 formed on the first wiring layer 201 and an electrode 201B-2 provided in the center of the spiral portion 201B-1. The electrode 201B-2 is connected to a wiring 211B of the third wiring layer 211 via a bump not shown (bump 221 in FIG. 3B) and then to the current control part 14 via a through via not shown (through via 214B in FIG. 3B). The first wiring layer 201 is patterned using a fine wiring fabrication process. This is suitable for a configuration of a long coil wiring of the inductor 152. As a non-limiting example, a wiring formation rule for the first wiring layer 201 is line/space: 2 µm/2 µm, and that for the third wiring layer 211 is line/space 10 µm/10 µm.

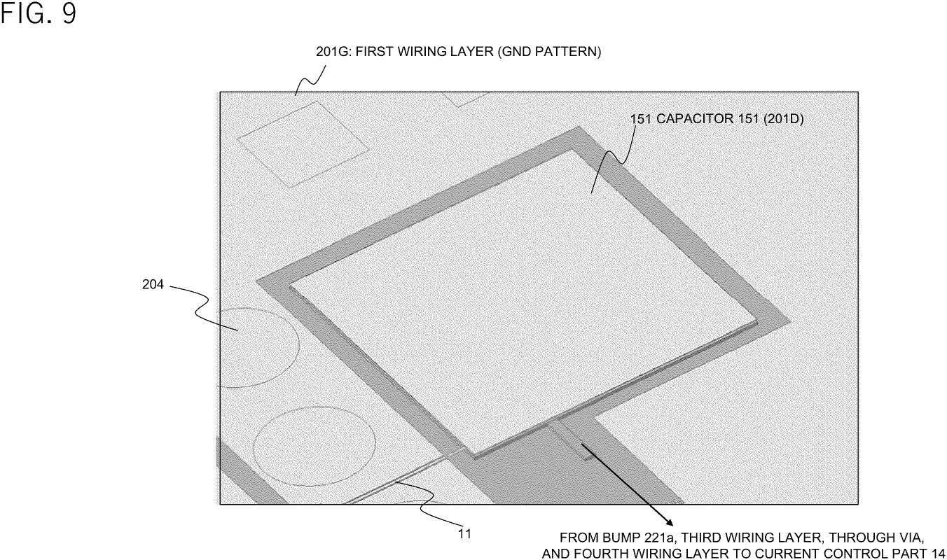

FIG. 9 illustrates a configuration of the capacitor 151. The capacitor 151 includes a wiring pattern (electrode) 201D on the first wiring layer 201 – a gap – a wiring pattern (electrode) 211B on the third wiring layer 211 (FIG. 3B). A height of the bump 221B is low (10 µm or less), and the bumps 221B forms a very narrow gap between the electrode 201D on the first wiring layer 201 and the electrode 211B on the third wiring layer 211. Note that a capacitance value of a parallel flat plate capacitor is proportional to S/d, where S is an area of an electrode and d is a gap between the electrodes. This configuration is advantageous for the formation of a large capacitance (capacitance value). Thicknesses of the quantum chip 200 and the interposer substrate 210 are, for example, about (or of an extent of) 300 µm for each, and a height of the bump 221 (FIG. 3A and FIG. 3B) disposed between the first wiring layer 201 and the third wiring layer 211 are, for example, about 3 µm.

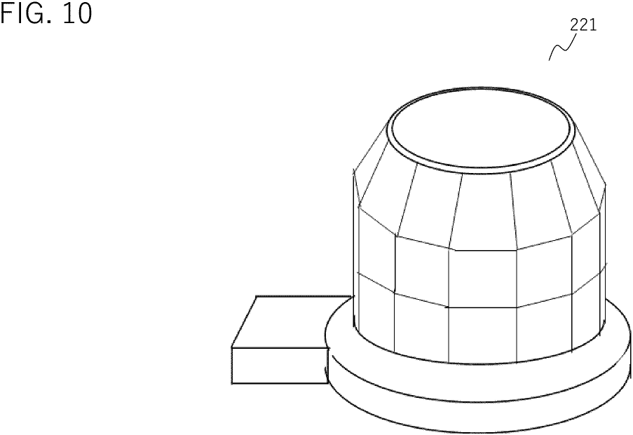

FIG. 10 schematically illustrates an example of the bump 221 (FIG. 3A and FIG. 3B) disposed between the first wiring layer 201 and the third wiring layer 211. The bump 221 is of a form of a circular cylinder or a polygonal cylinder with a top side chamfered. A surface of the bump 221 is coated with a superconducting material. The bump 221 connecting the first wiring layer 201 and the third wiring layer 211 may be bonded using such as solid-phase bonding.

FIG. 11A illustrates a model without electromagnetic field coupling measures in the example embodiment described with reference to FIG. 2. When through vias connecting a ground pattern on the first wiring layer 201 and a ground pattern (ground plane) on the second wiring layer 202, or bums connecting the ground pattern on the first wiring layer 201 and a ground pattern on the third wiring layer 211, are not sufficiently provided, an oscillation output (electromagnetic wave) of the Josephson parametric oscillator 10 on the first wiring layer 201 may propagate through a space between the first wiring layer 201 and the third wiring layer 211 to leak to the current control part 14. This is called “coupling by leakage”. Transmission line blocks of TL1 and TL2 represent the electrodes of the capacitor 151 provided on the first wiring layer 201 portion and the third wiring layer 211, respectively.

FIG. 11A illustrates a case where the leaked electromagnetic wave propagates through the first substrate 203 (a capacitor C3) and a capacitor C4) to a coupling portion of the inductor 152 of the parallel LC circuit 15 to cause electromagnetic coupling. FIG. 11A also illustrates a case where the leaked electromagnetic wave is radiated into a vacuum space (a gap between the first wiring layer 201 and the third wiring layer 211) to propagate to a coupling portion with the bump 221B via capacitors C5 and C6. Such a coupling due to leakage cannot be suppressed by the parallel LC circuit 15 and causes degradation of the characteristics of the resonator.

FIG. 11B illustrates a case in which in FIG. 11A, coupling due to leakage is reduced by a through via 204G and a bump 221G both connected to the ground potential and inserted in a coupling path due to leakage. That is, in a case when it is difficult to realize a qubit by a configuration illustrated in FIG. 11A, for the oscillator 10 in the first wiring layer 201, ground vias (through vias 204G connected to a ground plane 202G of the second wiring layer 202) and/or bumps (bumps 221G connected to a ground plane on the third wiring layer 211) are inserted in the coupling path due to leakage of the electromagnetic wave. The coupling path is set to ground potential. Coupling due to leakage of the electromagnetic wave can be avoided to enable the qubit circuit to operate. The performance of FIG. 5A described above can be realized only with such a configuration where the first wiring layer 201 of the quantum chip 200 is interposed between the ground surface on the second wiring layer 202 opposing to the first wiring layer 201 and the ground plane (pattern) on the third wiring layer 211 of the interposer substrate 210, using the bumps 221 and the through vias 204.

Each disclosure of PTL 1 and NPL 1 cited above is incorporated herein in its entirety by reference thereto. It is to be noted that it is possible to modify or adjust the example embodiments or examples within the whole disclosure of the present invention (including the Claims) and based on the basic technical concept thereof. Further, it is possible to variously combine or select a wide variety of the disclosed elements (including the individual elements of the individual claims, the individual elements of the individual examples and the individual elements of the individual figures) within the scope of the Claims of the present invention. That is, it is self-explanatory that the present invention includes any types of variations and modifications to be done by a skilled person according to the whole disclosure including the Claims, and the technical concept of the present invention.

What is claimed is:

1. A superconducting quantum circuit apparatus comprising:
a resonator including a SQUID (superconducting quantum interference device) including at least two Josephson junctions in a loop;
a magnetic field application part that includes a conductor portion, a current passing therethrough generating a magnetic flux penetrating through the SQUID, the current supplied from a current control part; and
a parallel LC circuit including an inductor and a capacitor each made of a superconducting material, the inductor and the capacitor having respective one ends connected in common to the magnetic field application part and respective other ends connected in common to a current path from the current control part.

2. The superconducting quantum circuit apparatus according to claim 1, wherein the resonator includes
a conductor portion of a superconducting material having a first edge connected to one end of the SQUID and a second edge capacitively coupling with a signal line, with an opposite end of the SQUID connected to ground.

3. The superconducting quantum circuit apparatus according to claim 2, comprising:
a quantum chip that includes:
a first substrate;
a first wiring layer disposed on one surface of the first substrate, the first wiring layer including
the resonator, and at least a part of the parallel LC circuit; and
a second wiring layer disposed on a surface opposite to the one surface of the first substrate; and
an interposer substrate that includes:
a second substrate;
a third wiring layer disposed on a one surface of the second substrate, arranged facing with the first wiring layer of the quantum chip, the third wiring layer including a wiring being connected to a corresponding wiring on the first wiring layer via a bump; and
a fourth wiring layer disposed on a surface opposite to the one surface of the second substrate, with a wiring on the third wiring layer and a corresponding wiring on the fourth wiring layer being connected by a through via formed through the second substrate,
wherein the conductor portion of the magnetic field application part is included in the first wiring layer or the third wiring layer.

4. The superconducting quantum circuit apparatus according to claim 3, wherein the capacitor included in the parallel LC circuit is constituted by a parallel flat plate capacitor including:
a first electrode formed on the first wiring layer; and
a second electrode formed on the third wiring layer, the first and second electrodes arranged facing each other via a gap between the first wiring layer and the third wiring layer, and wherein
the inductor included in the parallel LC circuit has one end connected to the magnetic field application part and the first electrode on the first wiring layer and has another end connected to the second electrode of the capacitor formed on the third wiring layer via the bump connecting the first wiring layer and the third wiring layer.

5. The superconducting quantum circuit apparatus according to claim 4, comprising:
at least one ground through via formed through the first substrate, the at least one ground through via connecting a ground pattern included in the first wiring layer to a ground pattern included in the second wiring layer on the first substrate of the quantum chip, and
at least one ground bump connecting the ground pattern included in the first wiring layer and a ground pattern included in the third wiring layer of the interposer substrate.

6. The superconducting quantum circuit apparatus according to claim 5, wherein the conductor portion of the resonator included in the first wiring layer is opposed to and capacitively coupled with a wiring pattern of the signal line included in the third wiring layer, via the gap between the first wiring layer and the third wiring layer.

7. The superconducting quantum circuit apparatus according to claim 1, wherein the parallel LC circuit is configured to suppress a passage of an electric power at a resonance frequency of the resonator to a side of the current control part, the resonance frequency being a frequency at which the resonator resonates due to a magnetic field coupling between the SQUID and the magnetic field application part.

8. The superconducting quantum circuit apparatus according to claim 1, wherein the parallel LC circuit has a resonance frequency equal to a resonance frequency of the resonator, an impedance of the parallel LC circuit seen from the resonator side is maximized at the resonance frequency of the resonator, which reduces a pass characteristic of an electromagnetic wave at the resonance frequency of the resonator to the current control unit side, wherein the superconducting quantum circuit apparatus includes
the current control part that supplies a direct current and/or an electromagnetic wave having a frequency equivalent to twice the frequency of the resonator from the current path to the magnetic field application part via the parallel LC circuit, the direct current and/or the electromagnetic wave not blocked by the parallel LC circuit.

9. The superconducting quantum circuit apparatus according to claim 4, wherein the quantum chip includes
one or more ground through vias formed through the first substrate to connect a planar ground pattern included in the first wiring layer to a planar ground pattern included in the second wiring layer.

10. The superconducting quantum circuit apparatus according to claim 9, wherein the one or more ground through vias inserted in a coupling path due to leakage to prevent an electromagnetic wave emitted from a predetermined first node of the resonator included in the first wiring layer of the quantum chip from propagating to the first substrate to couple with a second node on the second substrate side of the inductor of the parallel LC circuit.

11. The superconducting quantum circuit apparatus according to claim 4, comprising:
one or more ground bumps connecting a planar ground pattern formed on the first wiring layer of the quantum chip to a planar ground pattern formed on the third wiring layer of the interposer substrate.

12. The superconducting quantum circuit apparatus according to claim 11, wherein the one or more ground through vias inserted in a coupling path due to leakage to prevent an electromagnetic wave emitted from a predetermined first node of the resonator from propagating, via a gap between the first wiring layer and the third wiring layer to couple with a second node on the second substrate side of the inductor in the parallel LC circuit.

13. The superconducting quantum circuit apparatus according to claim 4, wherein the bump is of a shape selected from a group including columnar, conical, spherical and polygonal, a top of the bump formed to have a partially flat shape and a surface of the bump covered with a film of a superconducting material.
